(19) United States
(12) Patent Application Publication
(10) Pub. No.: US 2017/0018487 A1
(43) Pub. Date: Jan. 19, 2017

(54) THERMAL ENHANCEMENT FOR QUAD FLAT NO LEAD (QFN) PACKAGES

(71) Applicant: Broadcom Corporation, Irvine, CA (US)

(72) Inventors: Daijiao Wang, Walnut, CA (US); Jianjun Li, Irvine, CA (US); Chunwei Yu, Irvine, CA (US)

(21) Appl. No.: 14/805,945

(22) Filed: Jul. 22, 2015

Related U.S. Application Data
(60) Provisional application No. 62/192,856, filed on Jul. 15, 2015.

(51) Int. Cl. H01L 23/495; H01L 23/367; H01L 23/31; H01L 21/56; H01L 23/13; H01L 23/00

(52) U.S. Cl. CPC H01L 23/49568; H01L 23/13; H01L 24/49; H01L 23/3114; H01L 21/56; H01L 23/3675; H01L 23/49541; H01L 23/49503; H01L 23/49531; H01L 24/85; H01L 2224/4912; H01L 2224/4945; H01L 2924/14; H01L 2224/48245

(57) ABSTRACT

Integrated circuit packages with enhanced thermal characteristics are provided. For example, in embodiments, a QFN (quad flat no lead) package includes a die pad that extends to at least one pinless edge of the QFN package body. A portion of the die pad further extends towards a top surface of the QFN package body. By doing so, a low impedance thermal path from a die included in the QFN package to the top of the QFN package body is formed, which causes heat generated by the die to dissipate from one or more sides and the top of the QFN package, and ultimately to the surrounding environment. Furthermore, the path travelled by the heat in a circuit board coupled to the QFN package is shortened, thereby protecting electrical components coupled thereto.

### CROSS-REFERENCE TO RELATED APPLICATION(S)

This application claims the benefit of U.S. Provisional Application No. 62/192,856, filed Jul. 15, 2015, the entirety of which is incorporated by reference herein.

### BACKGROUND

Technical Field

Embodiments described herein relate to integrated circuit packaging technology and more particularly to quad flat no lead (QFN) packages.

Description of Related Art

Integrated circuit (IC) chips or dies from semiconductor wafers are typically interfaced with other circuits using a package that can be attached to a printed circuit board (PCB). One such type of IC die package is a quad flat package (QFP). A QFP is a multi-sided (e.g., four-sided) package that has leads extending from all sides. The leads are used to interface the QFP with a circuit board when the QFP is attached to the circuit board during a surface mount process.

A type of integrated circuit package that is similar to the QFP is a quad flat no lead (QFN) package. Similarly to a QFP, a QFN package has multiple sides (e.g., four sides), but does not have leads that extend outward from the sides of the package. Instead, a bottom surface of the QFN package has a centrally-located die pad and contacts/lands that may be referred to as “pins.” The die pad and the contact pins interface the QFN package with a circuit board when the QFN is attached to the circuit board during a surface mount process. An encapsulating material (e.g., a mold) covers the die over the top.

The encapsulating material is made from a low thermally conductive material. Thus, such packages have a relatively high thermal impedance from the die to the package top. Even though heat transfer from the package to the circuit board is effective through the die pad, this heat has to travel down to the ground plane of the circuit board through vias, and conduct away laterally from inside the circuit board back to the top of the circuit board, before dissipating into the environment.

### BRIEF SUMMARY

Methods, systems, and apparatuses are described for thermally enhanced QFN packages, substantially as shown in and/or described herein in connection with at least one of the figures, as set forth more completely in the claims

### BRIEF DESCRIPTION OF THE DRAWINGS/FIGURES

The accompanying drawings, which are incorporated herein and form a part of the specification, illustrate embodiments and, together with the description, further serve to explain the principles of the embodiments and to enable a person skilled in the pertinent art to make and use the embodiments.

FIG. 1 shows a cross-sectional view of an example QFN package in accordance with an embodiment.

FIG. 2 shows a top view of the QFN package of FIG. 1, in accordance with an embodiment.

FIG. 3 shows a cross-sectional view of a QFN package coupled to a substrate in accordance with an embodiment

FIG. 4 shows a cross-sectional view of a heat sink coupled to a QFN package in accordance with an embodiment.

FIG. 5 shows a cross-sectional view of a heat sink coupled to a QFN package in accordance with another embodiment.

FIG. 6 shows a cross-sectional view of a QFN package including a die pad and an encapsulating material having different thicknesses in accordance with an embodiment.

FIG. 7 shows a cross-sectional view of a QFN package including a die pad and an encapsulating material having different thicknesses in accordance with another embodiment.

FIG. 8 shows a cross-sectional view of a QFN package including a die pad that extends to two pinless edges in accordance with an embodiment.

FIG. 9 shows a top view of the QFN package of FIG. 8, in accordance with an embodiment.

FIG. 10 shows a cross-sectional view of a QFN package including a die pad that extends to three pinless edges in accordance with an embodiment.

FIG. 11 shows a top view of the QFN package of FIG. 10, in accordance with an embodiment.

FIG. 12 shows a flowchart providing an example process for assembling a QFN package having a die pad that extends to at least one pinless perimeter edge of its body in accordance with an embodiment.

The features and advantages of the subject matter of the present application will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### I. Introduction

The present specification discloses numerous example embodiments. The scope of the present patent application is not limited to the disclosed embodiments, but also encompasses combinations of the disclosed embodiments, as well as modifications to the disclosed embodiments.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

Furthermore, it should be understood that spatial descriptions (e.g., “above,” “below,” “up,” “left,” “right,” “down,” “top,” “bottom,” “vertical,” “horizontal,” etc.) used herein are for purposes of illustration only, and that practical implementations of the structures described herein can be spatially arranged in any orientation or manner.

Moreover, descriptive terms used herein such as “about,” “approximately,” and “substantially” have equivalent meanings and may be used interchangeably.

Numerous exemplary embodiments are now described. Any section/subsection headings provided herein are not intended to be limiting. Embodiments are described throughout this document, and any type of embodiment may be included under any section/subsection. Furthermore, it is contemplated that the disclosed embodiments may be combined with each other in any manner.

### II. Example Embodiments

Embodiments are described herein for integrated circuit packages with enhanced thermal characteristics. For example, in embodiments, a quad flat no-lead (QFN) package includes a die pad that extends to at least one pinless edge of the QFN package body. A portion of the die pad further extends towards a top surface of the QFN package body. By doing so, a low impedance thermal path from a die included in the QFN package to the top of the QFN package body is formed, which causes heat generated by the die to dissipate from one or more sides and the top of the QFN package, and ultimately to the surrounding environment. Furthermore, the length of the path travelled by the heat in a circuit board coupled to the QFN package is shortened, thereby protecting electrical components coupled thereto.

For instance, a QFN package is described herein. The QFN package includes a body having opposing first and second surfaces and a plurality of perimeter edges. The body includes a die pad having one or more first surfaces and a second surface opposing the one or more first surfaces of the die pad. A first of the one or more first surfaces of the die pad is configured to mount an integrated circuit die, and the second surface of the die pad forms a portion of the second surface of the body. The body further includes a plurality of pins peripherally positioned along a subset of the perimeter edges of the second surface of the body. At least one of the perimeter edges is pinless. The die pad extends to at least one pinless perimeter edge of the body.

A method for assembling a QFN package that includes a body having opposing first and second surfaces is also described herein. In accordance with the method, a lead frame is formed that includes a plurality of pins peripherally positioned along a subset of perimeter edges of the lead frame, wherein at least one of the perimeter edges is pinless, and a die pad having one or more first surfaces and a second surface opposing the one or more first surfaces of the die pad. A first of the one or more first surfaces of the die pad is configured to mount an integrated circuit die, the second surface of the die pad forms a portion of the second surface of the body, and the die pad extends to at least one pinless perimeter edge of the lead frame. The integrated circuit die is mounted to the die pad.

A no-lead integrated circuit (IC) package is further described herein. The no-lead IC package includes a body having opposing first and second surfaces and four perimeter edges. The body includes a die pad having one or more first surfaces and a second surface opposing the one or more first surfaces of the die pad. A first of the one or more first surfaces of the die pad is configured to mount an integrated circuit die, and the second surface of the die pad forms a portion of the second surface of the body. The body further includes a plurality of pins peripherally positioned along three of the four perimeter edges of the second surface of the body. The fourth perimeter edge of the perimeter edges is pinless. The die pad extends to at least one pinless perimeter edge of the body.

These and further embodiments are described in detail in the following section.

### III. Example QFN Package with Thermal Enhancement

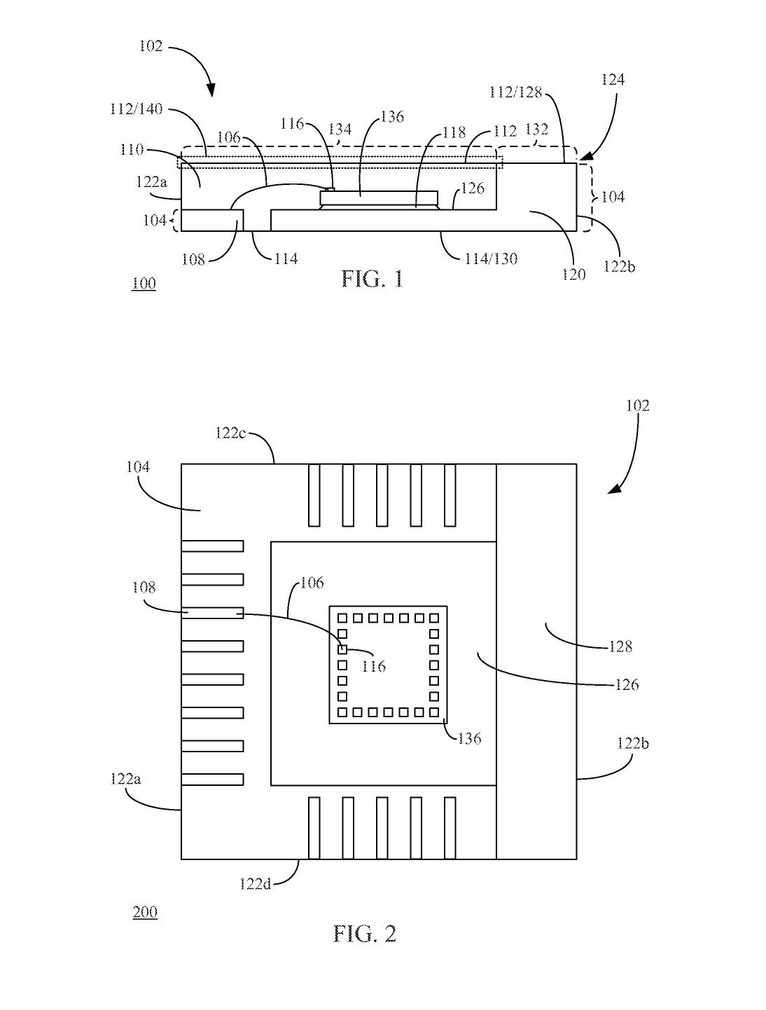

FIG. 1 shows a cross-sectional view 100 of an example QFN package 102 in accordance with an embodiment. FIG. 2 shows a top view 200 of QFN package 102. QFN package 102 includes a body 124 having a first surface 112, a second surface 114 that opposes first surface 112, and a plurality of perimeter edges 122a-d. Body 124 comprises an integrated circuit die/chip 136, a lead frame portion 104, one or more bond wires (also known as “wire bonds”) 106, and an encapsulating material 110. Lead frame portion 104 includes a plurality of pins 108 peripherally positioned along a subset of perimeter edges (e.g., perimeter edges 122a, 122c, and 122d in FIG. 2) and a die pad 120. Pins 108 are lands/contacts for mounting QFN package 102 to a substrate (e.g., a printed circuit board) during a surface mount process.

Die 136 is an integrated circuit chip/or die that includes a miniature electronic circuit formed of semiconductor devices. For example, die 136 may be separated (singulated) from a semiconductor wafer (e.g., silicon), where an array of integrated circuit chips/dies were formed (e.g., using photolithography or other process), or die 136 may be formed in another manner. As shown in FIG. 1, die 136 is mounted to a portion of die pad 120 (e.g., to a first surface 126 of die pad 120). Die 136 may be mounted to die pad 120 using an adhesive material 118. Adhesive material 118 may be any type of suitable adhesive material, including an epoxy, solder, glue, or other adhesive, which may be electrically conductive (e.g., a silver particle filled epoxy) or non-electrically conductive.

Die pad 120 is configured to dissipate heat generated by die 136. Die pad 120 may include one or more first surfaces 126, 128 and a second surface 130 that opposes one or more first surfaces 126, 128. Die pad 120 extends to perimeter edge 122b of body 124, which is a pinless perimeter edge (i.e., a perimeter edge without any pins 108). This advantageously causes heat to dissipate from a side (e.g., the side on which perimeter edge 122b is located) of QFN package 102. In accordance with an embodiment, to improve heat dissipation even further, one or more portions of die pad 120 may extend toward first surface 112 of body 124, thereby forming a portion of first surface 112. For example, as shown in FIG. 1, first surface 128 of die pad 120 forms a first portion 132 of first surface 112 of body 124 (e.g., is coplanar with first surface 112). This advantageously creates a low impedance thermal path from die 136 to the top (i.e., first surface 112) of QFN package 102, which enables heat to dissipate from a side (e.g., the side on which perimeter edge 122b is located) and the top of QFN package 102.

As shown in FIG. 1, bond wire(s) 106 are coupled between pads/terminals 116 of die 136 and one or more pins 108. It is noted that while FIGS. 1 and 2 only show one bond wire, QFN package 102 may include any number of bond wires, where each of the bond wires is coupled between a pad 116 of die 136 and one or more of pins 108. Bond wire(s) 106 may be wires formed of any suitable electrically conductive material, including a metal such as gold, silver, copper, aluminum, nickel, tin, other metal, or combination of metals/alloy. Bond wires 106 may be attached according to wire bonding techniques and mechanisms well known to persons skilled in the relevant art(s).

As further shown in FIG. 1, encapsulating material 110 covers die 136, first surface 126 of die paid 120, and bond wire(s) 106, and fills in regions between pins 108 and die pad 120 (encapsulating material 110 is shown as transparent in FIG. 2 for ease of illustration). A surface portion 140 of encapsulating material 110 forms a second portion 134 of first surface 112 of body 124. Encapsulating material 110 protects die 136 and bond wire(s) 106 from environmental hazards. Encapsulating material 110 may be any suitable type of encapsulating material, including an epoxy, a ceramic material, a plastic material, a mold compound, etc. Encapsulating material 110 may be applied in a variety of ways, including by a saw singulation technique, injection into a mold, etc.

Lead frame portion 104 may be made of an electrically conductive material, including a metal such as copper, aluminum, tin, nickel, gold, silver, or other metal, or a combination of metals/alloy, such as a solder, etc. One or more surfaces of lead frame portion 104 may optionally be coated with an electrically conductive material and/or be otherwise surface treated. The electrically conductive coatings may be any suitable electrically conductive material, including a metal such as copper, aluminum, tin, nickel, gold, silver, or other metal, or a combination of metals/alloy, such as a solder, etc. and may be formed on lead frame portion 104 in any manner, including by a plating technique (e.g., electroplating), a printing technique, photolithography, or other technique.

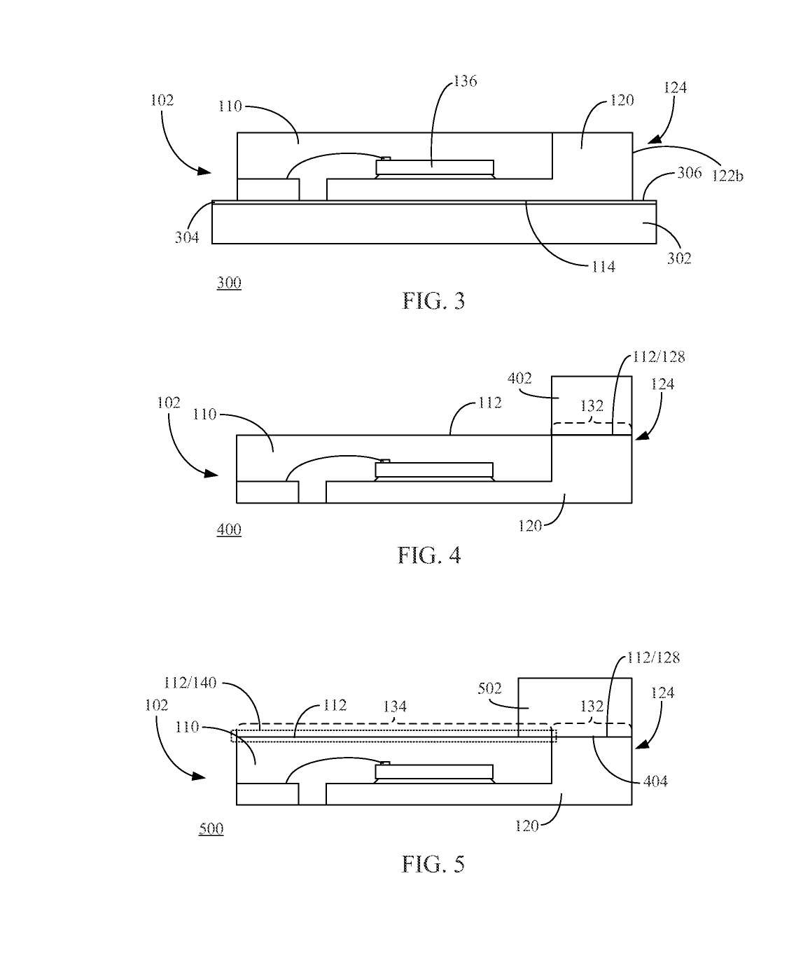

Second surface 114 of body 124 is formed by second surface 130 of lead frame 104, a surface of encapsulating material 114 and/or surfaces of pins 108. Second surface 114 of body 124 is configured to be mounted a substrate. For example, FIG. 3 shows a cross-sectional view 300 of QFN package 102 coupled to a substrate 302 in accordance with an embodiment. As shown in FIG. 3, second surface 114 of body 124 is mounted to substrate 302. Examples of substrate 302 include a printed circuit board (PCB), or any other support structure known in the art used to support semiconductor devices and hereinafter developed for performing functions of a printed circuit board. The term “printed circuit board” is defined as a board used to mechanically support and electrically connect electronic components using conductive pathways, tracks or signal traces etched from sheets of conductive material (e.g., one or more metals such as copper, aluminum, etc.) laminated onto a non-conductive substrate (e.g., plastic, fiberglass, or any other dielectric suitable to serve as a non-conductive substrate for a printed circuit board). The pathways, tracks or signal traces may form a layer (or “plane”) 304 of conductive material at a top surface 306 (i.e., the surface on which QFN package 102 is mounted) of substrate 302, and/or at other layers of substrate 302.

Die pad 120 may be directly coupled to plane 304 (e.g., via solder). Die pad 120 is coupled to plane 304 along the edge at which die pad 120 is extended (i.e., perimeter edge 122b). This advantageously shortens the path travelled by the heat generated by die 136 through substrate 302.

In accordance with one or more embodiments, a heat sink is mounted to first surface 112 of body 124 to further improve heat dissipation. For example, FIG. 4 shows a cross-sectional view 400 of a heat sink 402 coupled to QFN package 102 in accordance with an embodiment. As shown in FIG. 4, heat sink 402 is attached to portion 132 of first surface 112 that is formed by second surface 128 of die pad 120. Heat sink 402 may be attached/mounted to portion 132 using an adhesive material described elsewhere herein (e.g., adhesive material 118 of FIG. 1) or other type of adhesive material.

FIG. 5 shows a cross-sectional view 500 of a heat sink coupled to QFN package 102 in accordance with another embodiment. As shown in FIG. 5, heat sink 502 is coupled to both portion 132 of first surface 112 that is formed by second surface 128 of die pad 120 and portion 134 of first surface 112 that is formed by surface portion 140 of encapsulating material 110. As shown in FIG. 5, heat sink 502 is coupled to portion 134 such that portion 134 is partially exposed. However, in accordance with other embodiments, heat sink 502 has a width that is equal to or greater than the width of second portion 134 (or first surface 112) such that second portion 134 is not exposed. Heat sink 502 may be attached/mounted to portions 132 and/or 134 using an adhesive material described elsewhere herein (e.g., adhesive material 118 of FIG. 1) or other type of adhesive material.

While FIGS. 1 and 5 show first surface 128 of die pad 120 and surface portion 140 of encapsulating material 110 as being coplanar, in accordance with one or more embodiments, first surface 128 and surface portion 140 are not coplanar. For example, encapsulating material 110 and die pad 120 may have different thicknesses.

For instance, FIG. 6 shows a cross-sectional view 600 of QFN package 102, where die pad 120 has a larger thickness than encapsulating material 110 in accordance with an embodiment. As shown in FIG. 6, encapsulating material 110 has a first thickness of h1 and die pad 120 has a second thickness h2, which is greater than h1. In this embodiment, first surface 128 of die pad 120 protrudes from body 124. Accordingly, surface portion 140 of encapsulating material 110 is not coplanar with first surface 128. Protruding die pad 120 advantageously causes heat to dissipate from the top of QFN package 102 in a more effective manner.

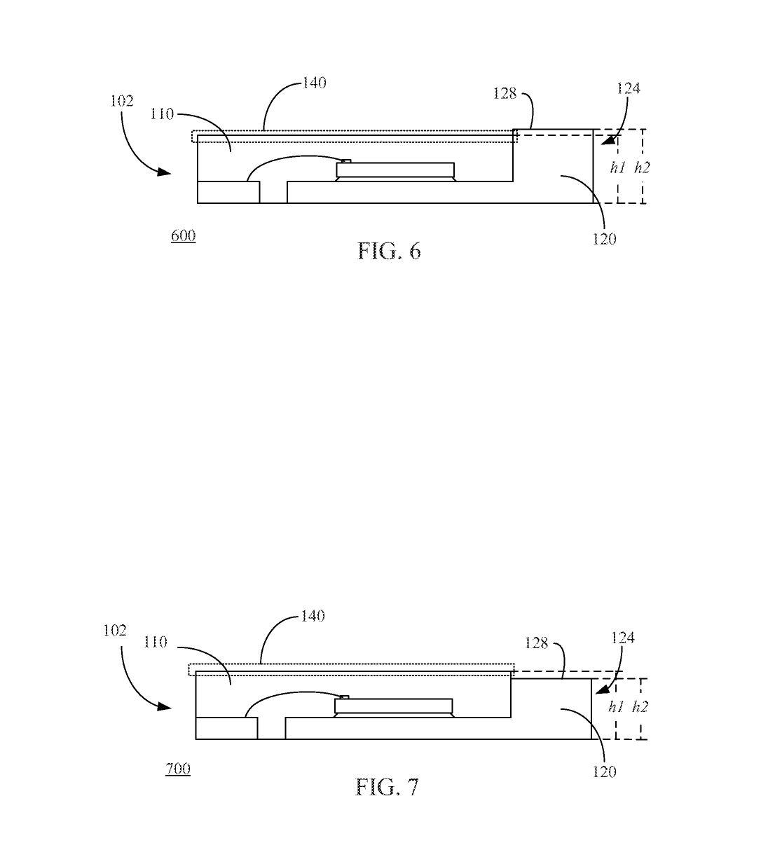

Alternatively, in accordance with one or more embodiments, encapsulation material 110 (and not die pad 120) protrudes from body 124. For example, FIG. 7 shows a cross-sectional view 700 of QFN package 102, where encapsulating material 110 has a larger thickness than die pad 120 in accordance with an embodiment. As shown in FIG. 7, encapsulating material 110 has a first thickness of h1 and die pad 120 has a second thickness h2, which is less than h1. In this embodiment, encapsulating material 110 protrudes from body 124. Accordingly, surface portion 140 of encapsulating material 110 is not coplanar with first surface 128.

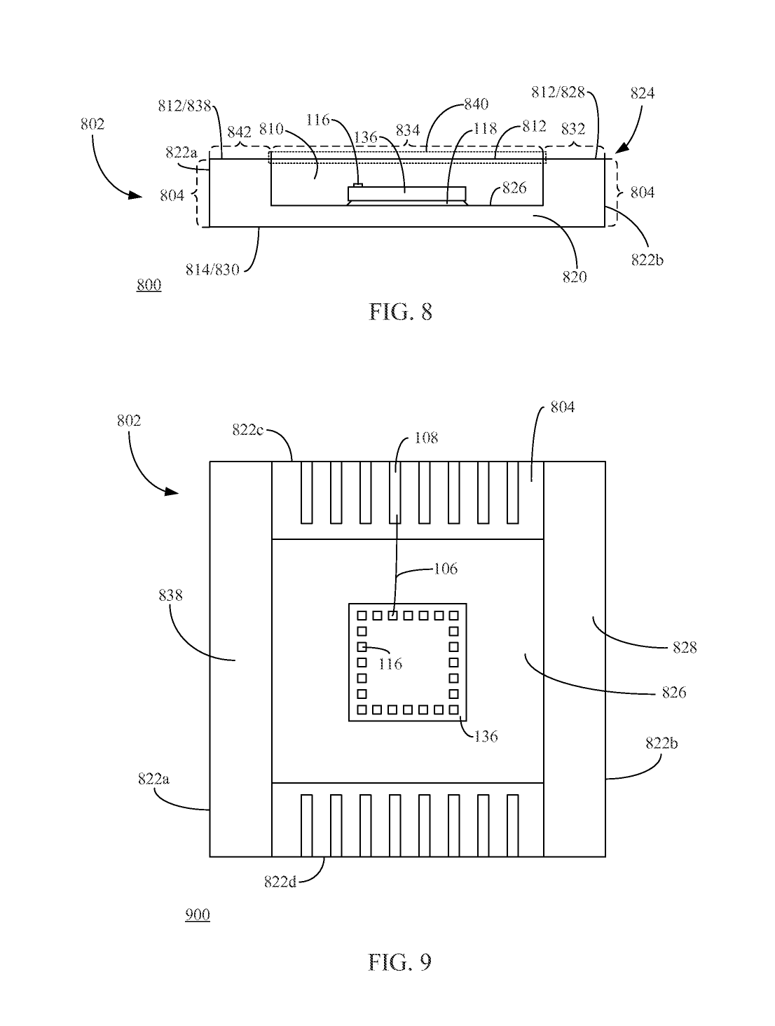

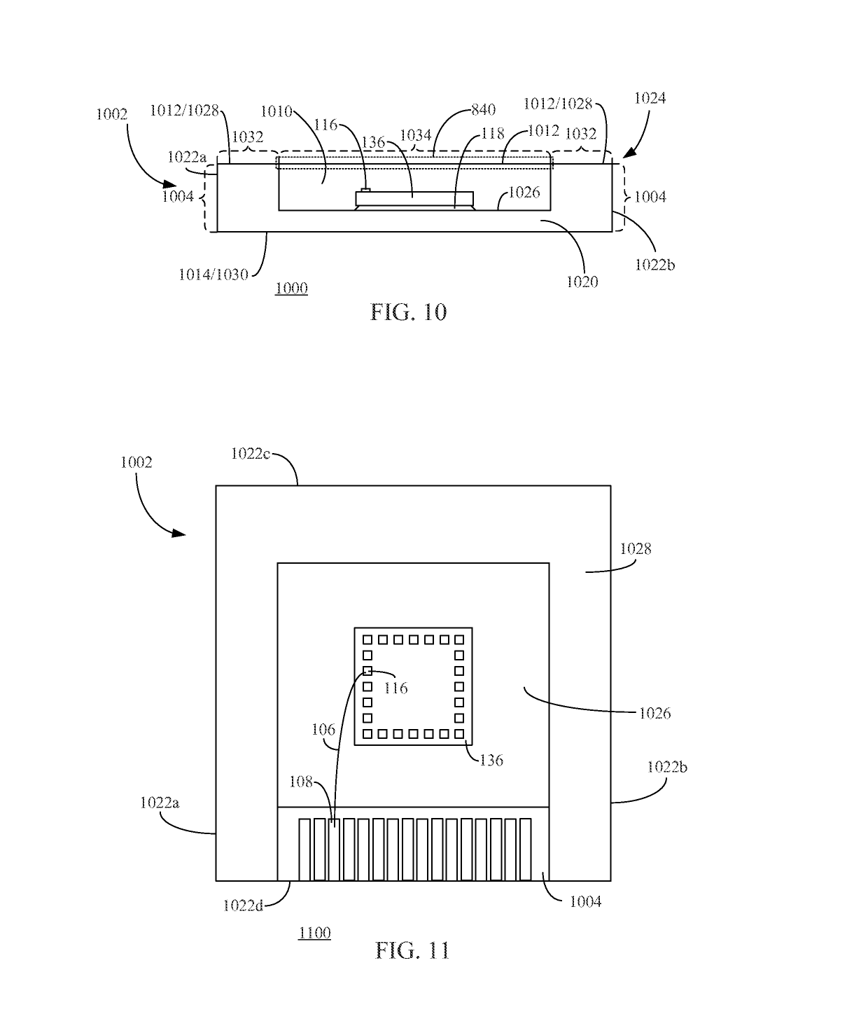

While FIGS. 1-7 show die pad 120 extending to one pinless edge (i.e., perimeter edge 122b) of body 124 of QFN package 102, in accordance with one or more embodiments, the die pad of a QFN package may extend to more than one pinless edge. This advantageously provides greater thermal conductivity due to greater exposure to the environment and/or enables better contact with a heat sink due to an increase of surface area on which the heat sink may be attached (although it is noted that in such embodiments, a larger number of pins are positioned into the remaining edges (i.e., the edges that are not pinless)). For example, FIG. 8 shows a cross-sectional view 800 of a QFN package 802 including a die pad that extends to two pinless edges in accordance with an embodiment. FIG. 9 shows a top view 900 of QFN package 802. Some features of QFN package 802 having names/reference numbers similar to those described above with respect to FIGS. 1-7 are not re-described below for purposes of brevity.

As shown in FIGS. 8 and 9, QFN package 802 includes a body 824 having a first surface 812, a second surface 814 that opposes first surface 812, and a plurality of perimeter edges 822a-d. Body 824 comprises an integrated circuit die/chip 136, a lead frame portion 804, one or more bond wires (also known as “wire bonds”) 106, and an encapsulating material 810. Lead frame portion 804 includes a plurality of pins 108 peripherally positioned along a subset of perimeter edges (e.g., perimeter edges 822c and 822d) and a die pad 820. Pins 108 are lands/contacts for mounting QFN package 802 to a substrate (e.g., a printed circuit board) during a surface mount process.

Die 136 is mounted to a portion of die pad 820 (e.g., to a first surface 826 of die pad 820). Die 136 may be mounted to die pad 820 using an adhesive material 118.

Die pad 820 is configured to dissipate heat generated by die 136. Die pad 820 may include one or more first surfaces 826, 828, and 836, and a second surface 830 that opposes one or more first surfaces 826, 828, and 838. Die pad 820 extends to perimeter edges 822a and 822b of body 824, which are pinless perimeter edges (i.e., a perimeter edges without any pins). This advantageously cause heat to dissipate from two sides (e.g., the sides on which perimeter edges 822a and 822b are respectively located) of QFN package 802. In accordance with an embodiment, to improve heat dissipation even further, one or more portions of die pad 820 may extend toward first surface 812 of body 824, thereby forming a portion of first surface 812. For example, as shown in FIG. 8, first surfaces 828, 838 of die pad 820 form first portions 832, 838 of first surface 812 of body 824. This advantageously creates a low impedance thermal path from die 136 to the top surface (i.e., first surface 812) of QFN package 802, which causes heat to dissipate from the two sides (e.g., the sides on which perimeter edges 822a and 822b are located) and the top surface of QFN package 802.

As further shown in FIG. 8, encapsulating material 810 covers die 136, second surface 826 of die pad 820, and bond wire(s) 106, and fills in regions between pins 108 and die pad 820 (encapsulating material 810 is shown as transparent in FIG. 9 for ease of illustration). A surface portion 840 of encapsulating material 810 forms a second portion 834 of first surface 812 of body 824.

Note that in the example of FIGS. 8 and 9, pinless perimeter edges 822a and 822b are opposing edges of QFN package 802. In another embodiment, pinless perimeter edges 822a and 822b are adjacent edges (share a same corner) of QFN package 802.

FIG. 10 shows a cross-sectional view 1000 of a QFN package 1002 including a die pad that extends to three pinless edges in accordance with an embodiment. FIG. 11 shows a top view 1100 of QFN package 1002. Some features of QFN package 1002 having names/reference numbers similar to those described above with respect to FIGS. 1-9 are not re-described below for purposes of brevity.

As shown in FIGS. 10 and 11, QFN package 1002 includes a body 1024 having a first surface 1012, a second surface 1014 that opposes first surface 1012, and a plurality of perimeter edges 1022a-d. Body 1024 comprises an integrated circuit die/chip 136, a lead frame portion 1004, one or more bond wires (also known as “wire bonds”) 106, and an encapsulating material 1010. Lead frame portion 1004 includes a plurality of pins 108 peripherally positioned along a subset of perimeter edges (e.g., perimeter edge 1022d) and a die pad 1020.

Die 136 is mounted to a portion of die pad 1020 (e.g., to a first surface 1026 of die pad 1020. Die 136 may be mounted to die pad 1020 using an adhesive material 118.

Die pad 1020 is configured to dissipate heat generated by die 136. Die pad 136 may include one or more first surfaces 1026 and 1028, and a second surface 1030 that opposes one or more first surfaces 1026 and 1028. Die pad 1020 extends to perimeter edges 1022a, 1002b, and 1022c of body 824, which are pinless perimeter edges (i.e., a perimeter edges without any pins). This advantageously cause heat to dissipate from three sides (e.g., the sides on which perimeter edges 1022a, 1022b, and 822c are respectively located) of QFN package 1002. In accordance with an embodiment, to improve heat dissipation even further, one or more portions of die pad 1020 may extend toward first surface 1012 of body 1024, thereby forming a portion of first surface 1012. For example, as shown in FIG. 10, first surface 1028 of die pad 1020 forms first portion 1032 of first surface 1012 of body 1024. This advantageously creates a low impedance thermal path from die 136 to the top surface (i.e., first surface 1012) of QFN package 1002, which causes heat to dissipate from the three sides (e.g., the sides on which perimeter edges 1022a, 1022b, and 1022c are located) and the top surface of QFN package 1002.

As further shown in FIG. 10, encapsulating material 1010 covers die 136, second surface 1026 of die pad 1020, and bond wire(s) 106, and fills in regions between pins 108 and die pad 1020 (encapsulating material 1010 is shown as transparent in FIG. 11 for ease of illustration). A surface portion 1040 of encapsulating material 1010 forms a second portion 1034 of first surface 1012 of body 1024.

Note that FIGS. 2, 9, and 11 show packages having sixteen pins, for ease of illustration. It is noted, however, that embodiments are applicable to packages having any number of pins. Embodiments are applicable to QFN packages having 3, 20, 32, and 68 pins, for instance.

It is further noted that while FIGS. 1-11 depict edges of a body of a QFN package as either having pins or being pinless, in accordance with one or more embodiments, one or more edge(s) may be partially pinless (where one or more portions of edge(s) include pins and other portion(s) of the edge(s) are pinless). In accordance with such embodiments, the die pad extends to the portion(s) of the edge(s) that are pinless.

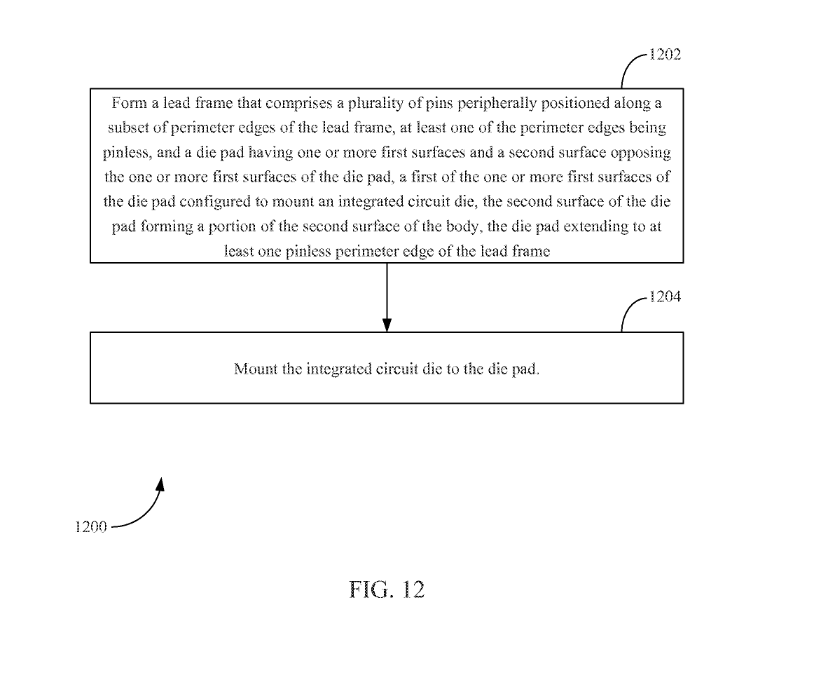

A QFN package with a die pad that extends to at least one pinless perimeter edge of its body, such as QFN packages 102, 802, and 1002, as respectively shown in FIGS. 1, 8, and 10, may be formed in any manner, including according to conventional package assembly processes or according to proprietary assembly processes. FIG. 12 shows a flowchart 1200 providing an example process for assembling a QFN package having a die pad that extends to at least one pinless perimeter edge of its body in accordance with an embodiment. For instance, QFN packages 102, 802, and 1002 may be formed according to flowchart 1200. Other structural and operational embodiments will be apparent to persons skilled in the relevant art(s) based on the discussion regarding flowchart 1200. Note that some conventional steps for assembling a QFN package may not be shown in FIG. 12 for purposes of brevity. Such conventional steps will be known to persons skilled in the relevant art(s). Flowchart 1200 is described as follows.

As shown in FIG. 12, a lead frame that comprises a plurality of pins peripherally positioned along a subset of perimeter edges of the lead frame, at least one of the perimeter edges being pinless, and a die pad having one or more first surfaces and a second surface that opposes the one or more first surfaces of the die pad are formed (1202). A first of the one or more first surfaces of the die pad is configured to mount an integrated circuit die, the second surface of the die pad forms a portion of the second surface of the body, and the die pad extends to at least one pinless perimeter edge of the lead frame. For example, with reference to FIG. 1, lead frame 104 is formed that comprises pins 108 that are peripherally positioned along a subset of perimeter edges 122a, 122c, and 122d, where at least one of the perimeter edges (i.e., perimeter edge 122b) is pinless. Lead frame 104 further comprises die pad 120 that has first surfaces 126, 128 and second surface 130 that opposes first surfaces 126, 128. First surface 126 is configured to mount die 136, and second surface 130 forms a portion of second surface 114 of body 124. As shown in FIG. 1, die pad 120 extends to perimeter edge 122c of lead frame 140.

Lead frame 104 may be formed according to any suitable process, including by a conventional lead frame fabrication process, or by a proprietary process. For example, in an embodiment, lead frame 104 may be formed by receiving a foil or sheet of an electrically conductive material, and etching, cutting, or otherwise forming pins 108, die pad 120, and/or other features in the foil or sheet. Such etching or cutting may be performed using chemical etching, photolithography, laser etching, mechanical etching, a punching mechanism, or other suitable process. Alternatively, lead frame 104 may be formed by injecting an electrically conductive material into a mold chamber. Lead frame 104 may be made of any suitable electrically conductive material, including a metal such as copper, aluminum, tin, nickel, gold, silver, or other metal, or combination of metals/alloy, or any other suitable electrically conductive material, as would be known to persons skilled in the relevant art(s). Note that lead frame 104 may be formed individually, or may be formed in a strip of lead frames 104 or a panel (e.g., array) of lead frames 104, to be used to form multiple QFN packages. The strip or panel may be separated into individual lead frames 104 prior to performing further steps of flowchart 1200, at any point during flowchart 1200.

Continuing with flowchart 1200, the integrated circuit die is mounted to the die pad (1204). For example, with reference to FIG. 1, die 136 is mounted to first surface 126 of die pad 120. Die 136 may be attached to first surface 126 in any manner, such as by adhesive material 118 shown in FIG. 1 and described above. Die 136 may be placed on die pad 120 using a pick-and-place machine, or any other suitable mechanism otherwise known to persons skilled in the relevant art(s). Die 136 may be mounted to any portion of first surface 126, including a central location (e.g., the center) or an off center location.

In accordance with one or more embodiments, a plurality of bond wires are attached between a plurality of pads of the integrated circuit die and the plurality of pins. For example, as shown in FIG. 1, bond wire(s) 106 are attached between pads 116 of die 136 and pins 108.

In accordance with one or more embodiments, a second of the one or more first surfaces of the die pad forms a first portion of the first surface of the body. For example, with reference to FIG. 1, first surface 128 of die pad 120 forms a first portion 132 of first surface 112 of body 124.

In accordance with one or more embodiments, the integrated circuit die and the first of the one or more first surfaces of the die pad are encapsulated with an encapsulating material, where a surface portion of the encapsulating material forms a second portion of the first surface of the body. For example, with reference to FIG. 1, die 136 and first surface 126 of die pad 120 are encapsulated with encapsulating material 110. Surface portion 140 of encapsulating material 110 forms second portion 134 of first surface 112 of body 124.

In accordance with one or more embodiments, a heat sink is mounted to at least the second of the one or more first surfaces of the die pad. For example, as shown in FIG. 4, heat sink 402 is mounted to first surface 128 of die pad 120. In another example, as shown in FIG. 5, heat sink 502 is mounted to first surface 128 and surface portion 140 of encapsulating material 110.

Heat sink 402 and/or heat sink 502 may be coupled directly to first surface 128 and/or surface portion 140 using an adhesive material (e.g., a thermally conductive adhesive material that includes a thermally conductive material, such as a metal such as silver, etc.).

In accordance with one or more embodiments, the second of the one or more first surfaces of the die pad and the surface portion of the encapsulating material are coplanar. For example, as shown in FIG. 1, first surface 128 of die pad 120 and surface portion 140 of encapsulating material are coplanar.

### IV. Conclusion

Embodiments are described herein having various shapes, sizes, numbers, and combinations of extended leads (in a lead frame) and pins (in a package). Embodiments described herein may include any number and combination of shapes of the extended leads/pins described herein, and any variations/modifications thereof. Note that the embodiments described herein may be combined in any manner.

While various embodiments have been described above, it should be understood that they have been presented by way of example only, and not limitation. It will be apparent to persons skilled in the relevant art that various changes in form and detail can be made therein without departing from the spirit and scope of the embodiments. Thus, the breadth and scope of the embodiments should not be limited by any of the above-described exemplary embodiments, but should be defined only in accordance with the following claims and their equivalents.

What is claimed is:

1. A quad flat no-lead (QFN) package, comprising:
a body having opposing first and second surfaces and a plurality of perimeter edges, the body comprising:
a die pad having one or more first surfaces and a second surface opposing the one or more first surfaces of the die pad, a first of the one or more first surfaces of the die pad configured to mount an integrated circuit die, the second surface of the die pad forming a portion of the second surface of the body, and
a plurality of pins peripherally positioned along a subset of the perimeter edges of the second surface of the body, at least one of the perimeter edges being pinless; and
the die pad extending to at least one pinless perimeter edge of the body.

2. The QFN package of claim 1, wherein a second of the one or more first surfaces of the die pad forms a first portion of the first surface of the body.

3. The QFN package of claim 2, wherein the second of the one or more first surfaces of the die pad is configured to mount a heat sink.

4. The QFN package of claim 2, further comprising:
an encapsulating material that encapsulates the integrated circuit die and the first of the one or more surfaces of the die pad, a surface portion of the encapsulating material forming a second portion of the first surface of the body.

5. The QFN package of claim 4, wherein the second of the one or more first surfaces of the die pad and the surface portion of the encapsulating material are coplanar.

6. The QFN package of claim 1, wherein the die pad is configured to be mounted to a printed circuit board.

7. The QFN package of claim 1, further comprising:
a plurality of bond wires coupled between a plurality of pads of the integrated circuit die and the plurality of pins.

8. A method for assembling a quad flat no-lead (QFN) package comprising a body having opposing first and second surfaces, comprising:
forming a lead frame that comprises:
a plurality of pins peripherally positioned along a subset of perimeter edges of the lead frame, at least one of the perimeter edges being pinless; and
a die pad having one or more first surfaces and a second surface opposing the one or more first surfaces of the die pad, a first of the one or more first surfaces of the die pad configured to mount an integrated circuit die, the second surface of the die pad forming a portion of the second surface of the body, the die pad extending to at least one pinless perimeter edge of the lead frame; and
mounting the integrated circuit die to the die pad.

9. The method of claim 8, wherein a second of the one or more first surfaces of the die pad forms a first portion of the first surface of the body.

10. The method of claim 9, further comprising:
mounting a heat sink to at least the second of the one or more first surfaces of the die pad.

11. The method of claim 9, further comprising:
encapsulating the integrated circuit die and the first of the one or more first surfaces of the die pad with an encapsulating material, wherein a surface portion of the encapsulating material forms a second portion of the first surface of the body.

12. The method of claim 11, wherein the second of the one or more first surfaces of the die pad and the surface portion of the encapsulating material are coplanar.

13. The method of claim 8, further comprising:
attaching a plurality of bond wires between a plurality of pads of the integrated circuit die and the plurality of pins.

14. A no-lead integrated circuit (IC) package, comprising:
a body having opposing first and second surfaces and four perimeter edges, the body comprising:
a die pad having one or more first surfaces and a second surface opposing the one or more first surfaces of the die pad, a first of the one or more first surfaces of the die pad configured to mount an IC die, the second surface of the die pad forming a portion of the second surface of the body, and
a plurality of pins peripherally positioned along three of the four perimeter edges of the second surface of the body, a fourth perimeter edge of the perimeter edges being pinless; and
the die pad extending to the fourth perimeter edge of the body.

15. The no-lead IC package of claim 14, wherein a second of the one or more first surfaces of the die pad forms a first portion of the first surface of the body.

16. The no-lead IC package of claim 15, wherein the second of the one or more first surfaces of the die pad is configured to mount a heat sink.

17. The no-lead IC package of claim 15, further comprising:
an encapsulating material that encapsulates the integrated circuit die and the first of the one or more surfaces of the die pad, a surface portion of the encapsulating material forming a second portion of the first surface of the body.

18. The no-lead IC package of claim 17, wherein the second of the one or more first surfaces of the die pad and the surface portion of the encapsulating material are coplanar.

19. The no-lead IC package of claim 14, wherein the die pad is configured to be mounted to a printed circuit board.

20. The no-lead IC package of claim 14, further comprising:
a plurality of bond wires coupled between a plurality of pads of the integrated circuit die and the plurality of pins.
